(19) United States
(12) Patent Application Publication
(10) Pub. No.: US 2026/0157029 A1
(43) Pub. Date: Jun. 4, 2026

(54) LIGHT EMITTING DEVICE AND LIGHT EMITTING DISPLAY DEVICE INCLUDING THE SAME

(71) Applicant: LG Display Co., Ltd., Seoul (KR)

(72) Inventors: Yu Jeong LEE, Paju-si (KR); Eun Jung PARK, Paju-si (KR); Ju Hyuk KWON, Paju-si (KR); Hyun Jin CHO, Paju-si (KR)

(73) Assignee: LG Display Co., Ltd., Seoul (KR)

(21) Appl. No.: 19/376,658

(22) Filed: Oct. 31, 2025

(30) Foreign Application Priority Data
Dec. 3, 2024 (KR) 10-2024-0177770

(51) Int. Cl. H10K 50/16; H10K 101/40

(52) U.S. Cl. CPC H10K 50/166; H10K 2101/40

(57) ABSTRACT

A light emitting device and a light emitting display device including the same are discussed. The light emitting device can include a first electrode and a second electrode facing each other, and a first light emitting layer, an electron transport stack, and a charge generation layer provided between the first electrode and the second electrode. The electron transport stack includes a first material layer adjacent to the first light emitting layer and including a single first material, a second material layer adjacent to the charge generation layer and including a single second material different from the first material, and a combination layer of the first material and the second material disposed between the first material layer and the second material layer.

### CROSS-REFERENCE TO RELATED APPLICATIONS

This application claims priority to Korean Patent Application No. 10-2024-0177770, filed in the Republic of Korea on Dec. 3, 2024, which is hereby expressly incorporated by reference as if fully set forth herein.

### BACKGROUND

### Technical Field

The present disclosure relates to a display device. More specifically, the present disclosure relates to a light emitting device that is imparted with improved efficiency and lifespan by changing a configuration of an electron transport layer and a light emitting display device including the same.

### Discussion of the Related Art

With the advent of the information society, displays for visually expressing electrical information signals have rapidly developed. In response to this, a variety of display devices with excellent performance such as slimness, low weight, and low power consumption are being developed.

Among such display devices, a light emitting display device that does not require a separate light source to realize compactness and clear color and has a light emitting device in a display panel has been considered as a competitive application.

The light emitting device can include an anode and a cathode facing each other as electrodes, a light emitting layer between the anode and the cathode, and a common layer for transferring holes and electrons to the light emitting layer.

Meanwhile, the light emitting device can include various functional layers for various functions, for example, in the common layer. The functional layers include a hole transport layer for transferring holes to the light emitting layer and the electron transport layer for transferring electrons to the light emitting layer.

In addition, recently, light emitting devices applied to light emitting display devices require or use a plurality of light emitting stacks to further improve luminous efficacy.

### SUMMARY OF THE DISCLOSURE

Accordingly, the present disclosure is directed to a light emitting device and a light emitting display device including the same that substantially obviate one or more problems due to limitations and disadvantages of the related art.

In a light emitting device, a plurality of functional layers adjacent to the electron transport layer are different, so that an energy barrier can occur at each interface when electrons are transferred from the plurality of function layers adjacent to the electron transport layer to the light emitting layer through the electron transport layer. This can cause a decrease in the efficiency of the light emitting device and can also cause a decrease in the lifespan due to the accumulation of electrons at each interface.

In addition, in a light emitting device including multiple light emitting stacks, such a decrease in electron transport efficiency and accumulation of carriers can occur in each of the multiple light emitting stacks, which can cause a further decrease in lifespan.

To address these issues, a light emitting device according to aspects of the present disclosure includes an electron transport stack that increases the electron transport efficiency from adjacent layers to the light emitting layer in a structure having multiple stacks, thereby improving efficiency and lifespan of the light emitting device.

Additional advantages, objects, and features of the disclosure will be set forth in part in the description which follows and in part will become apparent to those having ordinary skill in the art upon examination of the following or can be learned from practice of the invention. The objectives and other advantages of the disclosure can be realized and attained by the structure particularly pointed out in the written description and claims hereof as well as the appended drawings.

To achieve these objects and other advantages and in accordance with the purpose of the disclosure, as embodied and broadly described herein, a light emitting device includes a first electrode and a second electrode facing each other, and a first light emitting layer, an electron transport stack, and a charge generation layer provided between the first electrode and the second electrode, wherein the electron transport stack includes a first material layer adjacent to the first light emitting layer and including a single first material, a second material layer adjacent to the charge generation layer and including a single second material different from the first material, and a combination layer of the first material and the second material between the first material layer and the second material layer.

In another aspect of the present disclosure, a light emitting display device includes a substrate on which a plurality of sub-pixels is disposed, a pixel circuit provided in each of the plurality of sub-pixels, a first electrode connected to a thin film transistor of the pixel circuit in each of the plurality of sub-pixels, a second electrode facing the first electrode, and a first light emitting stack, a charge generation layer including an n-type charge generation layer and a p-type charge generation layer, and a second light emitting stack, provided between the first electrode and the second electrode, wherein the first light emitting stack includes a light emitting layer and an electron transport stack, the light emitting layer includes first, second and third color light emitting layers emitting light of different colors, and the electron transport stack includes a first material layer adjacent to the first to third color light emitting layers and including a single first electron transport material, a second material layer adjacent to the n-type charge generation layer and including a single second electron transport material different from the first electron transport material, and a combination layer of the first electron transport material and the second electron transport material between the first material layer and the second material layer.

It is to be understood that both the foregoing general description and the following detailed description of the present disclosure are examples and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a cross-sectional view illustrating a light emitting device according to a first embodiment of the present disclosure;

FIG. 2 is an energy band diagram of a light emitting layer, an electron transport stack, and a charge generation layer of FIG. 1 according to an embodiment of the present disclosure;

FIG. 3 illustrates a form of a first material;

FIG. 4 illustrates Fermi energy levels of the first material and a second material;

FIG. 5 is a diagram comparing Fermi energy levels of an undoped n-type charge generation layer and a doped n-type charge generation layer;

FIG. 6 illustrates Fermi energy levels of an adjacent second material layer and an n-type charge generation layer;

FIG. 7 is a graph showing JV characteristics a first EOD device having an electron injection layer using electron transport materials with different LUMO energy levels;

FIG. 8 is a graph showing JV characteristics of a second EOD device having an n-type charge generation layer using electron transport materials with different LUMO energy levels;

FIGS. 9A to 9C are energy band diagrams of light emitting devices of Experimental Examples 1 to 3;

FIGS. 10A and 10B are energy band diagrams of light emitting devices according to Experimental Examples 4 and 5;

FIG. 11 is a graph showing changes in lifespan and driving voltage of light emitting devices of Experimental Examples 1, 4, and 5;

FIG. 12 is a graph showing the lifespan and driving voltage change of the light emitting devices of Experimental Example 1 and Experimental Examples 8 to 10;

FIG. 13 is a cross-sectional view illustrating a light emitting device according to a second embodiment of the present disclosure;

FIGS. 14A and 14B are cross-sectional views illustrating modifications of the first embodiment of the present disclosure;

FIG. 15 is a cross-sectional view illustrating a light emitting device according to a third embodiment of the present disclosure;

FIG. 16 is a cross-sectional view illustrating a light emitting display device according to the first embodiment of the present disclosure;

FIG. 17 is a cross-sectional view illustrating a light emitting display device according to the second embodiment of the present disclosure;

FIG. 18A is an energy band diagram of a first material layer of an electron transport stack adjacent to a red light emitting layer; and

FIG. 18B is an energy band diagram of a first material layer of an electron transport stack adjacent to a green light emitting layer.

### DETAILED DESCRIPTION OF THE EMBODIMENTS

The same reference numbers will be used throughout the drawings to refer to the same or like parts. In the following description, detailed descriptions of technologies or configurations related to the present disclosure can be omitted so as to avoid unnecessarily obscuring the subject matter of the present disclosure. In addition, the names of devices used in the following description are selected in consideration of clarity of description of the disclosure, and can differ from the names of devices of actual products.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations can be omitted. In addition, the names of elements used in the following description are selected in consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the terms such as LUMO (lowest unoccupied molecular orbital) energy level and HOMO (highest occupied molecular orbital) energy level of a layer refer to the LUMO energy level and HOMO energy level of a material that occupies most of a weight ratio of the layer, for example, a host material, unless the context clearly mentions that the LUMO energy level and the HOMO energy level mean the LUMO energy level and HOMO energy level of a dopant material with which the layer is doped, respectively.

Here, the HOMO energy level is obtained by measuring the voltage corresponding to a first peak at which electrons are discharged from a target material through cyclic voltammetry (CV) while comparing with a reference material whose HOMO energy level is known. For example, the HOMO energy level of a substance can be measured based on a substance whose oxidation potential and reduction potential are known.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30 wt %, based on a total weight of the first material in the doped layer. A “doped” layer can be a layer in which a host material can be distinguished from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” layer refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which reflects the inherent characteristics of an emissive material such as a dopant material or a host material included in an organic emission layer, by (b) an outcoupling emittance spectrum curve, which is determined by the structure and optical characteristics of an organic light-emitting element including the thicknesses of organic layers such as, for example, an electron transport layer.

Hereinafter, example embodiments of the present disclosure will be described in detail with reference to the accompanying drawings. In adding reference numerals to elements of each of the drawings, although the same elements are illustrated in other drawings, like reference numerals can refer to like elements. All the components of each display device/apparatus according to all embodiments of the present disclosure are operatively coupled and configured.

Hereinafter, the light emitting device and the light emitting display device including the same according to the present disclosure will be described with reference to the drawings.

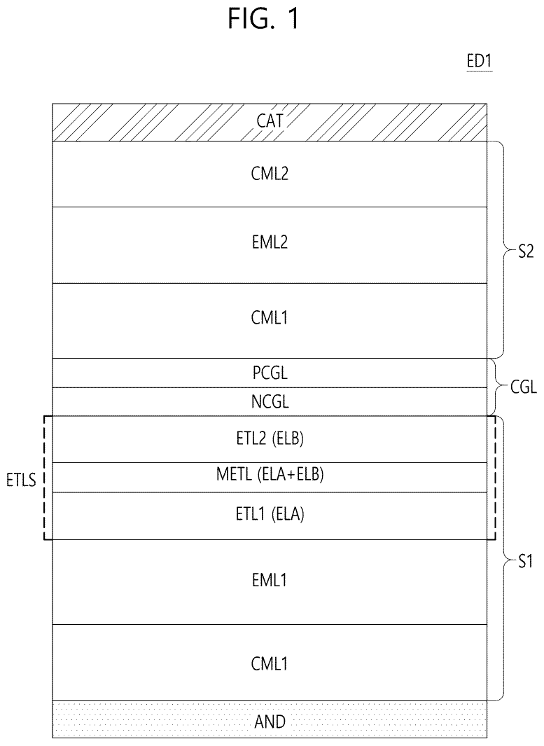

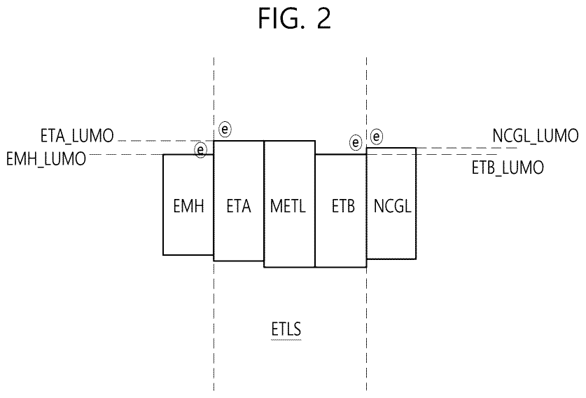

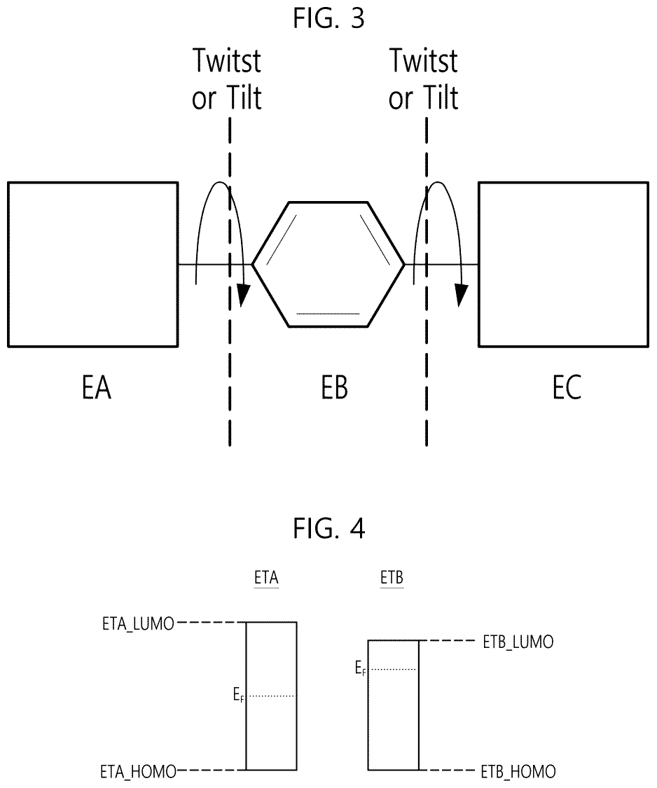

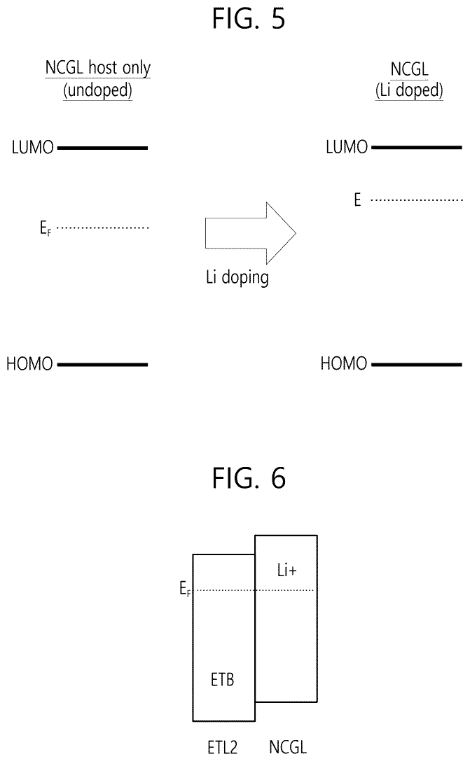

FIG. 1 is a cross-sectional view illustrating a light emitting device according to a first embodiment of the present disclosure. FIG. 2 is an energy band diagram of a light emitting layer, an electron transport stack, and a charge generation layer of FIG. 1 according to an embodiment of the present disclosure. FIG. 3 illustrates a form of a first material. FIG. 4 illustrates Fermi energy levels of the first material and a second material. FIG. 5 is a diagram comparing Fermi energy levels of a undoped n-type charge generation layer and a doped n-type charge generation layer. FIG. 6 illustrates Fermi energy levels of an adjacent second material layer and an n-type charge generation layer.

As shown in FIG. 1, the light emitting device ED1 according to the first embodiment of the present disclosure includes a first electrode AND and a second electrode CAT facing each other, and a plurality of light emitting stacks S1 and S2 between the first and second electrodes AND and CAT. The light emitting device ED1 includes a charge generation layer CGL between the plurality of light emitting stacks S1 and S2.

The example illustrated in FIG. 1 shows a case in which two light emitting stacks S1 and S2 are disposed between the first electrode AND and the second electrode CAT, but the embodiment of the present disclosure is not limited thereto. For example, the light emitting devices of the embodiments of the present disclosure can have three or more light emitting stacks disposed between the first electrode AND and the second electrode CAT.

Recently, light emitting devices included in light emitting display devices include a plurality of light emitting stacks and thus are used to achieve remarkable high luminance.

When the light emitting device includes a plurality of light emitting stacks, it includes a charge generation layer between adjacent light emitting stacks to supplement insufficient holes and electrons while moving away from the electrode.

The charge generation layer CGL disposed between adjacent light emitting stacks S1 and S2 can include, for example, an n-type charge generation layer NCGL that generates electrons and transfers the electrons to the lower light emitting stack, and a p-type charge generation layer PCGL that generates holes and transfers the holes to the upper light emitting stack. In some cases, the charge generation layer CGL can be provided as a single layer.

Each light emitting stack S1 and S2 can include a hole transport common layer CML1, a light emitting layer EML1, or EML2, and an electron transport common layer CML2.

At least one of the first electrode AND and the second electrode CAT is transparent or semi-transparent, and light generated in the light emitting device ED1 is transmitted through the transparent or semi-transparent electrode. For example, when the first electrode AND includes a reflective electrode and the second electrode CAT includes a semi-transparent or transparent electrode, the light emitting device ED1 can be a top-emission type. As another example, when the first electrode AND includes a transparent electrode and the second electrode CAT includes a reflective electrode, the light emitting device ED1 can be a bottom-emission type. As another example, the first electrode AND and the second electrode CAT can be transparent or semi-transparent electrodes, so that the light emitting device ED1 can emit light in both directions.

The first electrode AND can function as an anode, and the second electrode CAT can function as a cathode. The first electrode AND can be connected to the thin film transistor of the pixel circuit provided in each sub-pixel on the substrate. The second electrode CAT can be provided in common to each sub-pixel and can receive a common voltage signal at least from the outside.

The hole transport common layer CML1 can include, for example, at least one of a hole injection layer, a hole transport layer, or an electron blocking layer. The hole injection layer can be selectively provided only in the first light emitting stack S1 located at the lowest position between the first electrode AND and the second electrode CAT. In this case, the hole injection layer can be in contact with the first electrode AND.

The electron transport common layer CML2 can include, for example, at least one of a hole blocking layer, an electron transport layer, or an electron injection layer.

The electron injection layer can be optionally provided in the uppermost light emitting stack located at the highest position between the first electrode AND and the second electrode CAT and can be in contact with the second electrode CAT.

In the light emitting device according to the embodiment of the present disclosure, an electron transport stack ETLS is provided between at least the first light emitting layer EML1 of the first light emitting stack S1 and the n-type charge generation layer NCGL.

The electron transport stack ETLS includes a first material layer ETL1 including only a first material ETA adjacent to the first light emitting layer EML1, a second material layer ETL2 including only a second material ETB different from the first material ETA adjacent to the n-type charge generation layer NCGL, and a combination layer METL of the first material ETA and the second material ETB between the first material layer ETL1 and the second material layer ETL2.

Referring to FIG. 2, a detailed structure of the electron transport stack ETLS will be described.

The first material ETA has a first LUMO energy level ETA_LUMO, which is higher than the LUMO energy level EMH_LUMO of the host EMH of the first light emitting layer EML1. Therefore, electrons move from the higher LUMO energy level of the first material layer ETL1 including only the first material ETA to the lower LUMO energy level of the first light emitting layer EML1, so that there is no barrier to the movement of electrons and the electron accumulation phenomenon at the interface of the light emitting layer EML1 and the electron transport stack ETLS can be prevented.

In addition, the second material ETB has a second LUMO energy level ETB_LUMO, which is lower than the LUMO energy level NCGL_LUMO of the n-type charge generation layer NCGL. Therefore, when electrons move from the higher LUMO energy level of the n-type charge generation layer NCGL to the lower LUMO energy level of the second material layer ETL2 including only the second material ETB, there is no barrier to electron movement, and the electron accumulation phenomenon at the interface of the n-type charge generation layer NCGL and the electron transport stack ETLS can be prevented.

When, contrary to the structure of FIG. 2, the LUMO energy level of the electron transport area is high and the LUMO energy level of the electron injection area is low, the higher LUMO energy level of the electron transport area acts as a barrier to the electron flow, which increases the driving voltage and can cause a delay in electron injection. In addition, this delay in electron injection can cause electron accumulation at the interface between the electron transport layer and the electron injection layer, which can be a major cause of reduction in lifespan of the light emitting device.

Here, the property that the first material ETA has a high LUMO energy level means that the first LUMO energy level ETA_LUMO of the first material ETA is similar to the vacuum energy level and has a shallow LUMO energy level. In contrast, the property that the second material ETB has a deep LUMO energy level means that the LUMO energy level is far from the vacuum level.

Since the LUMO energy level and HOMO energy level are measured based on the level of the vacuum state, the LUMO energy level and HOMO energy level are obtained as negative (−) values. Therefore, the relationship of the high and low LUMO energy levels compared herein results in the negative value compared to the vacuum level state.

When one of the two materials has a shallow LUMO energy level and the other material has a deep LUMO energy level, the absolute value of the deep LUMO energy level is greater than the absolute value of the shallow LUMO energy level.

The electron transport stack ETLS according to an embodiment of the present disclosure is disposed between the first light emitting layer EML1 and the n-type charge generation layer NCGL, and the first material layer ETL1 including only the first material ETA is disposed adjacent to the first light emitting layer EML1, and the second material layer ETL2 including only the second material ETB is disposed adjacent to the n-type charge generation layer NCGL. Electrons are sequentially transferred in the direction in which electrons are transported from the n-type charge generation layer NCGL to the first light emitting layer EML1 at both interfaces of the electron transport stack ETLS.

The electron transport stack ETLS of the embodiments of the present disclosure includes the combination layer METL in which the first material ETA and the second material ETB are mixed between the first material layer ETL1 and the second material layer ETL2.

The formation of the first material layer ETL1, the combination layer METL, and the second material layer ETL2 of the electron transport stack ETLS can be performed in the same chamber. A first material deposition source and a second material deposition source are disposed side by side on the lower side in the chamber. The formation surface of the substrate faces the first and second material deposition sources. The substrate is moved such that supply of the first material deposition source is independently performed first, and supply of the second material deposition source is independently performed later, and the first material layer ETL1 of the first material ETA alone, the combination layer METL of the first and second materials ETA and ETB, and the second material layer ETL2 of the second material ETB alone are sequentially formed on the substrate.

The first and second materials ETA and ETB are each electron transport materials, and as shown in FIG. 2, the first LUMO energy level ETA_LUMO of the first material ETA can be higher than the second LUMO energy level ETB_LUMO of the second material ETB.

In addition, the absolute value of the first LUMO energy level ETA_LUMO of the first material ETA can be smaller than the absolute value of the second LUMO energy level ETA_LUMO of the second material ETB.

Meanwhile, the first light emitting layer EML1 can include a dopant depending on the color of light emitted from the first light emitting layer EML1 along with the host EMH of the first light emitting layer EML1. The number of hosts included in the first light emitting layer EML1 can be one or more. In some cases, the host included in the first light emitting layer EML1 can include a plurality of hosts with different mobilities or transport properties. When the first light emitting layer EML1 includes a hole transport host and an electron transport host in the light emitting device according to one embodiment of the present disclosure, the LUMO energy level of the electron transport host can act as the LUMO energy level EMH_LUMO of the first light emitting layer EML1 at the interface with the electron transport stack ETLS in the electron flow.

The LUMO energy level of the first light emitting layer EML1 can be determined by the LUMO energy level of the host material contained in a relatively high content in the first light emitting layer EML1.

The first light emitting layer EML1 can have different host and dopant materials contained depending on the color of emitted light. In any case, when the first LUMO energy level ETA_LUMO of the first material layer ETL1 of the adjacent electron transport stack ETLS has a higher relationship than the LUMO energy level EMH_LUMO of the host EMH of the first light emitting layer EML1, electron transport is possible from the first material layer ETL1 to the first light emitting layer EML1 without a barrier.

The characteristic that the second material layer ETL2 and the first material layer ETL1 that contact the n-type charge generation layer NCGL and the first light emitting layer EML1 of both interfaces are formed of a single material in the electron transport stack ETLS is important for electron flow. In the electron transport stack ETLS, in order for the second material layer ETL2 and the first material layer ETL1 that contact the n-type charge generation layer NCGL and the first light emitting layer EML1 of both interfaces to function to assist electron transport, the first and second material layers ETL1, ETL2 each have a thickness of 25 Å or more. The electron transport stack ETLS is disposed between the first light emitting layer ETL1 and the n-type charge generation layer NCGL and functions to transport electrons to the first light emitting layer ETL1. As the thickness of the electron transport stack ETLS increases, the driving voltage of the light emitting device increases. Therefore, in order to prevent an increase in the driving voltage, the total thickness of the electron transport stack ETLS is set to be higher than 70 Å and not higher than 350 Å. More preferably, the total thickness of the electron transport stack ETLS can be 100 Å or more and 250 Å or less. In addition, the first and second material layers ETL1 and ETL2, each of which is a single layer, contact the first light emitting layer EML1 and the n-type charge generation layer NCGL, and in order to prevent an energy barrier at the interface, the total thickness of the first and second material layers ETL1 and ETL2 within the electron transport stack ETLS is greater than or equal to the thickness of the combination layer METL. The thickness of the combination layer METL can be greater than 1% and not greater than 50% of the total thickness of the electron transport stack ETLS.

For example, when the total thickness of the electron transport stack ETLS is 100 Å and the thicknesses of the first and second material layers ETL1 and ETL2 are the same, the thickness of each of the first and second material layers ETL1, ETL2 is not less than 25 Å and is less than 49.5 Å.

For example, when the total thickness of the electron transport stack ETLS is 200 Å, and the thicknesses of the first and second material layers ETL1 and ETL2 are the same, the thickness of each of the first and second material layers ETL1 and ETL2 is not less than 50 Å and is less than 99 Å.

The first material ETA can have a relatively shallow LUMO energy level among the electron transport materials, and can have a wider bandgap than the second material ETB, the host EMH of the first light emitting layer EMH, and the n-type charge generation layer NCGL.

For example, the first material ETA can be formed by bonding a weak donor moiety EA on one side to a strong acceptor moiety EC on the other side via a linker EB therebetween, as shown in FIG. 3.

The linker EB can be, for example, an arene derivative having 5 or more carbon atoms.

Examples of the weak donor moiety EA can include benzofuran, benzothiophene, dibenzofuran, dibenzothiophene, and the like.

Examples of the strong acceptor moiety EC can include pyrimidine, pyrazine, pyridazine, triazine, and the like containing two or more nitrogen atoms.

The first material ETA has a shallow LUMO energy level and a wide energy band gap. In order to have a wide energy band gap, the first material has a weak donor moiety EA, as shown in FIG. 3. In addition, the first material ETA includes a strong acceptor moiety EC and thus has bipolarity.

Meanwhile, the energy band gap of a material tends to widen as conjugation in the compound constituting the material becomes shorter.

Accordingly, the first material ETA can adopt a structure that reduces effective conjugation by introducing a tilt or twist at a specific angle within the molecule so as to provide a wide energy band gap.

On the other hand, the second material ETB can be provided to have a molecular structure in which an electron transport unit and a neutral unit are bound. Alternatively, the second material ETB can be formed by bonding a unit having weak hole mobility to the electron transport unit instead of a neutral unit. In this case, the second material ETB can have unipolarity, unlike the first material ETA.

In addition, the second material ETB has a planar or linear structure in which the internal molecular bonding within the material is well packed, so that the effective conjugation is large and the energy band gap is small compared to the first material ETA.

As shown in FIG. 4, the first and second materials ETA and ETB differ in high and low LUMO energy levels. The first and second materials ETA and ETB can have almost similar HOMO energy levels. The flow of electrons from the n-type charge generation layer NCGL to the first light emitting layer EML1 is determined by the LUMO energy levels of the first and second materials ETA and ETB, and although there is a difference in the HOMO energy levels of the first and second materials ETA and ETB, this difference does not affect the flow of electrons.

The second material ETB, which has a lower LUMO energy level than the first material ETA, has a higher Fermi energy level than the first material ETA.

Meanwhile, the material for the n-type charge generation layer NCGL can be doped with 10 wt % or less of an alkali metal, an alkaline earth metal, or a transition metal. Examples of the metal doping the N-type charge generation layer NCGL include lithium (Li), sodium (Na), potassium (K), rubidium (Rb), cesium (Cs), francium (Fr), magnesium (Mg), and ytterbium (Yb).

For example, as shown in FIG. 5, when comparing the case where the n-type charge generation layer NCGL_H includes only the host material without doping with the case where the host material of the n-type charge generation layer is doped with lithium ions (NCGL_H+Li+), the LUMO energy level NCGL_LUMO and the HOMO energy level NGGL_HOMO do not change in both cases, but lithium ion doping causes the material of the n-type charge generation layer to be coordinated with lithium, so that the Fermi energy level increases toward the LUMO energy level.

Therefore, the light emitting device according to the embodiment of the present disclosure is formed by bringing the second material layer ETL2 formed of only the second material ETB in contact with the lithium-doped n-type charge generation layer NCGL, and as shown in FIG. 4, the lithium-ion-doped n-type charge generation layer NCGL and the second material ETB as shown in FIG. 6 have similar high Fermi energy levels, so that such similar Fermi energy levels facilitate electron movement. Accordingly, in the light emitting device according to the embodiment of the present disclosure, electron movement between the n-type charge generation layer NCGL and the second material ETB is easy and electron injection characteristics are increased.

In an embodiment, the effect of the light emitting device in which the first light emitting layer of FIG. 1 is formed as a blue light emitting layer will be described.

The HOMO energy level, LUMO energy level, and energy band gap of the first and second materials included in the electron transport stack ETLS, the host BEMH of the blue light emitting layer adjacent to the electron transport stack ETLS, and the host NCGLH of the n-type charge generation layer are shown in Table 1.

TABLE 1

| | HOMO | LUMO | Eg |
|---|---|---|---|
| Material | [eV] | [eV] | [eV] |
| BEMH | −6.05 | −3.05 | 3.00 |
| ETA | −6.12 | −2.55 | 3.57 |
| ETB | −6.17 | −3.02 | 3.15 |
| NCGLH | −6.06 | −2.80 | 3.26 |

Here, the host BEMH of the blue light emitting layer is a compound with anthracene as the core and examples thereof include compounds, BH1, BH2, and BH3 below.

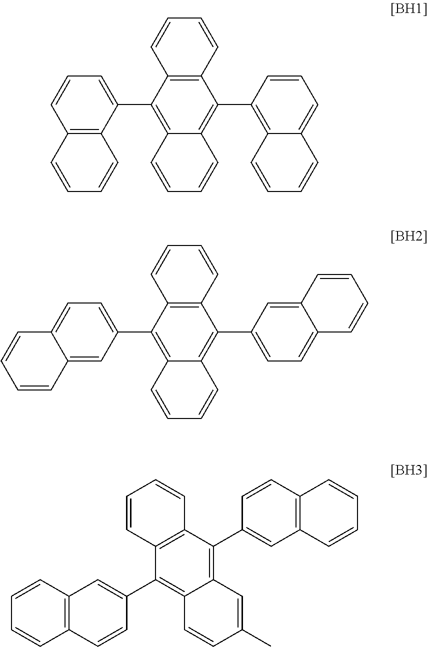

The host NCGLH of the n-type charge generation layer can be, for example, NCG1 or NCG2.

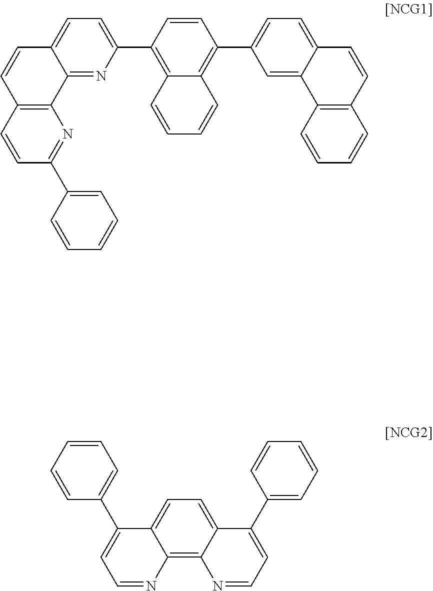 [SMILES: c1ccc(-c2ccc3ccc4ccc(-c5ccc(-c6ccc7ccc8ccccc8c7c6)c6ccccc56)nc4c3n2)cc1 ; c1ccc(-c2ccnc3c2ccc2c(-c4ccccc4)ccnc23)cc1]

The host NCGLH of the n-type charge generation layer includes, as a core, a molecular structure that is capable of binding to an alkali metal, an alkaline earth metal, or a transition metal used as a doping metal. The examples of NCG1 and NCG2 include phenanthroline, but the host of the n-type charge generation layer of the present disclosure is not limited thereto. Any compound capable of generating and transferring electrons and capable of binding to an alkali metal, alkaline earth metal, or transition metal used as a doping metal can be used.

Therefore, when the n-type charge generation layer is doped with an alkali metal, alkaline earth metal, or transition metal, the unshared electron pair of nitrogen in the compound binds to the doped metal, thus providing increased conductivity and low resistance. The concentration of the metal that is doped is set to 0.1 wt % to 10 wt % with respect to the n-type charge generation layer.

The second material ETB has a LUMO energy level that is at least lower than the LUMO energy level of the host of the n-type charge generation layer, and the LUMO energy levels of the second material ETB and the n-type charge generation layer can be 0.1 eV or higher and 0.5 eV or lower.

The second material ETB has a smaller energy band gap than the first material ETA.

Hereinafter, the electron injection behaviors of the first material ETA and the second material ETB will be described with reference to experiments.

The experiments were performed by evaluating the electron injection characteristics using the first to fourth materials ETA, ETB, ETC, and ETD with different LUMO energy levels in the same first and second EOD devices, respectively.

TABLE 2

| Material | LUMO energy level [eV] |
|---|---|
| ETA | −2.55 |
| ETB | −3.02 |
| ETC | −3.23 |
| ETD | −3.33 |

The LUMO energy level of the first material ETA among the materials used in Table 2 is the highest (shallowest). The LUMO energy level gradually decreases from the first material ETA to the fourth material ETD. The LUMO energy levels set forth in Table 2 are evaluated compared to the vacuum state level and are negative values. In Table 2, the LUMO energy level of the first material ETA is the highest. When the absolute values of the LUMO energy levels of the first to fourth materials ETA, ETB, ETC, ETC are evaluated, the absolute value of the LUMO energy level of the fourth material ETD is the highest.

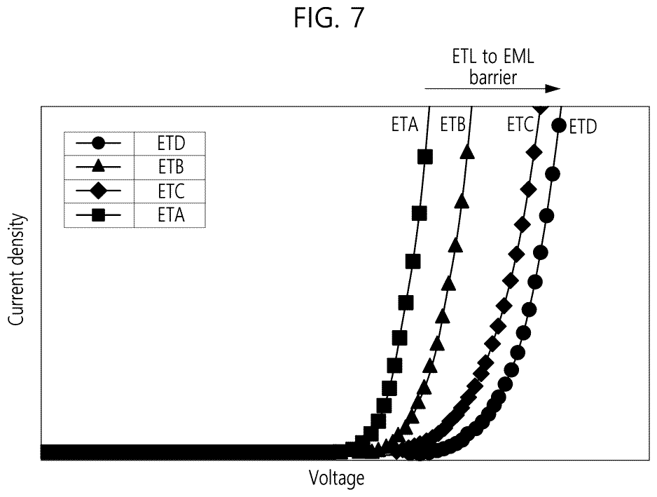

FIG. 7 is a graph showing the JV characteristics of the first EOD device having an electron injection layer using electron transport materials with different LUMO energy levels.

The change in current density as a function of the driving voltage of the first EOD device, which depends on the electron transport material adjacent to the light emitting layer, will be described.

The first EOD device includes a stack of a first electrode, a first electron injection layer, a hole blocking layer, a light emitting layer, a first electron transport layer, a second electron transport layer, a second electron injection layer, and a second electrode.

The first electrode was formed of ITO (indium tin oxide) and the second electrode was formed of aluminum (Al).

The first and second electron injection layers were commonly formed of LiF.

The light emitting layer contains the host BEMH of the blue light emitting layer of Table 1 described above and the blue dopant. The host BEMH of the blue light emitting layer has a LUMO energy level of −3.05 eV and a HOMO energy level of −6.05 eV.

The first electron transport layer in contact with the light emitting layer is formed using the first to fourth materials ETA, ETB, ETC, ETD having different LUMO energy levels, as shown in Table 2.

The second electron transport layer in contact with the second electron injection layer is formed of an electron transport material having a LUMO energy level similar to that of LiF constituting the second electron injection layer, so that almost no energy barrier occurs at the interface between the second electron injection layer and the second electron transport layer. This focuses on the change in characteristics according to the change in the material of the first electron transport layer in contact with the blue light emitting layer in experiments using the first EOD device.

As shown in FIG. 7, when the first electron transport layer includes the first material ETA having a shallower LUMO energy level, the current density changes at a low operating voltage, but when a material having a lower (deeper) LUMO energy level is used as the material for the first electron transport layer, the turn-on voltage increases and the current density changes at a higher voltage.

For example, it was found that the electron injection characteristics are superior as LUMO energy level of the material for the first electron transport layer in the first EOD device increases.

In the experiment, it was found that the LUMO energy level of the host BEMH of the blue light emitting layer is −3.05 eV, and the first material ETA having a LUMO energy level higher than −3.05 eV exhibits superior electron injection characteristics.

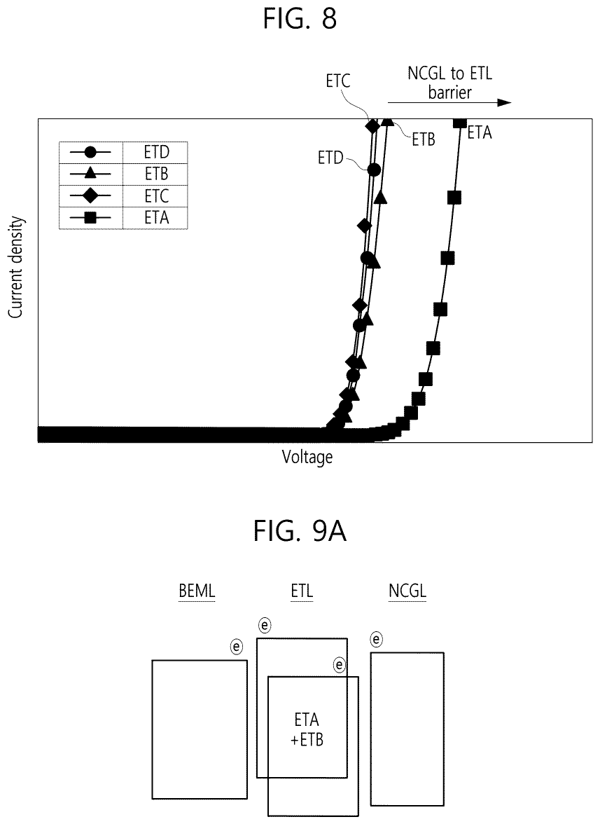

FIG. 8 is a graph showing the JV characteristics of the second EOD device having an n-type charge generation layer using electron transport materials with different LUMO energy levels.

The change in current density as a function of the driving voltage of the second EOD device, which depends on the electron transport material adjacent to the n-type charge generation layer, will be described.

The second EOD device includes a stack of a first electrode, an electron injection layer, a hole blocking layer, a light emitting layer, an electron transport layer, an n-type charge generation layer, and a second electrode.

The first electrode was formed of ITO (indium tin oxide) and the second electrode was formed of aluminum (Al).

The electron injection layer was commonly formed of LiF.

The light emitting layer included the host BEMH of the blue light emitting layer shown in Table 1 described above and the blue dopant. The host BEMH of the blue light emitting layer has a LUMO energy level of −3.05 eV and a HOMO energy level of −6.05 eV.

The electron transport layer in contact with the light emitting layer is formed using the first to fourth materials ETA, ETB, ETC, and ETD having different LUMO energy levels, as shown in Table 2.

The n-type charge generation layer used the NCG1 material described above. The LUMO energy level of the NCG1 material is −2.80 eV.

As shown in FIG. 8, when the electron transport layer includes second to fourth materials ETB, ETC, ETD having deeper LUMO energy levels than the first material ETA, the current density changes at a low operating voltage.

For example, when a material having a lower (deeper) LUMO energy level is used as the material for the first electron transport layer to transfer electrons from the n-type charge generation layer to the electron transport layer, the turn-on voltage increases and the current density changes at a higher voltage.

For example, it was found that the electron injection characteristics are superior as LUMO energy level of the material for the first electron transport layer in the first EOD device increases.

In the experiment, it was found that the LUMO energy level of the host BEMH of the blue light emitting layer is −3.05 eV, and the first material ETA having a LUMO energy level higher than −3.05 eV exhibits superior electron injection characteristics. As can be seen from FIG. 8, the second to fourth materials ETB, ETC, and ETD having the HOMO energy level lower than the HOMO energy level of the n-type charge generation layer, except for the first material ETA higher than the HOMO energy level of the n-type charge generation layer, have low turn-on voltages and thus have current density changes in a low driving voltage range.

Hereinafter, the significance of the structure of FIG. 1 of the present disclosure will be described.

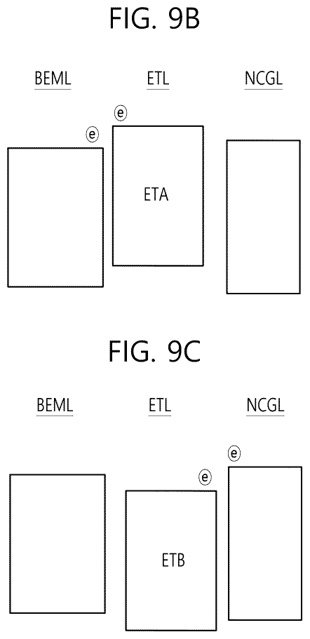

FIGS. 9A to 9C are energy band diagrams of the light emitting devices of Experimental Examples 1 to 3.

Experimental Examples 1 to 3 EX1, EX2, EX3 have the same structure as in FIG. 1, except that the electron transport stack structure is changed to a single-layer electron transport layer.

Each light emitting device of Experimental Examples 1 to 3 EX1, EX2, EX3 includes a first common layer CML1 including a hole injection layer HIL, a hole transport layer HTL, and an electron blocking layer EBL, a blue light emitting layer BEML including a blue host BEMH and a blue dopant BD on the first common layer CML1, an electron transport layer ETL, and an n-type charge generation layer NCGL sequentially laminated between the first electrode AND and the second electrode CAT.

Here, the first electrode AND is formed of ITO and the second electrode CAT is formed of aluminum (Al).

The blue light emitting layer BEML is formed using one of the hosts of BH1 to BH3 described above and a boron-based blue dopant.

The electron transport layers ETL differ in Experimental Examples 1, 2 and 3 EX1, EX2, EX3 as follows.

The N-type charge generation layer NCGL contains the material for the NCG1 or NCG2 as a host and is doped with lithium ions.

As shown in FIG. 9A, the light emitting device of Experimental Example 1 EX1 is formed throughout the entire thickness by co-depositing the first material ETA and the second material ETB in a content ratio of 1:1, instead of the electron transport stack of FIG. 1.

The properties of the first and second materials ETA and ETB are shown in Table 1. The first material ETA has a higher (shallower) LUMO energy level and thus has good electron injection efficiency from the electron transport layer to the light emitting layer. The second material ETB has a lower (deeper) LUMO energy level and thus has good electron injection efficiency from the n-type charge generation layer to the electron transport layer.

As shown in FIG. 9B, the light emitting device of Experimental Example 2 EX2 has an electron transport layer including a single first material ETA, instead of the electron transport stack of FIG. 1.

As shown in FIG. 9C, the light emitting device of Experimental Example 3 EX3 has an electron transport layer including a single second material ETB, instead of the electron transport stack of FIG. 1.

The experimental results in Table 3 below show the effects of Experimental Examples 2 and 3 EX2 and EX3 based on the measured values of Experimental Example 1 EX1.

TABLE 3

| | IVL (10 mA/cm²) | | | | | | |
|---|---|---|---|---|---|---|---|
| | | Luminance | Illuminance | | luminance/CIEy | 100 mA/cm² | Lifespan |
| | Voltage[V] | [%] | [%] | QE[%] | [%] | Voltage [V] | (T95[%]) |
| EX1 | Vr1 | 100 | 100 | 100 | 100 | Vr2 | 100 |
| EX2 | Vr1 + 0.08 | 98 | 96 | 98 | 98 | Vr2 + 0.05 | 119 |
| EX3 | Vr1 − 0.04 | 96 | 97 | 95 | 95 | Vr2 − 0.02 | 71 |

As shown in Table 3, Experimental Example 1 EX1 includes the first and second materials ETA and ETB with different LUMO energy levels and thus exhibits superior luminance, illuminance, quantum efficiency (QE), and CIEy, compared to Experimental Examples 2 and 3 EX2 and EX3 including a single material. This means that the electron injection characteristics from the n-type charge generation layer to the light emitting layer were improved, which increased the exciton density in the light emitting layer and increased the TTF (triplet-triplet fusion) efficiency, thereby improving the blue efficiency.

However, as shown in Table 3, Experimental Example 1 EX1 had a low lifespan compared to Experimental Example 2 EX2 using a single first material ETA. In other words, it can be seen that the lifespan is limited when electron transport materials with different LUMO energy levels are simply co-deposited.

As shown in FIGS. 1 and 2, the light emitting device of the present disclosure includes, as a structure of an electron transport stack ETLS, including a first material layer ETL1 of a single first material ETA adjacent to a first light emitting layer EML1, and a second material layer ETL2 of a single second material ETB adjacent to an n-type charge generation layer NCGL, and a combination layer METL in which the first and second materials are mixed between the first and second material layers, to constitute a plurality of layers.

The following experiments show the results when the single material adjacent to the first light emitting layer and the n-type charge generation layer is different in the configuration of the electron transport stack.

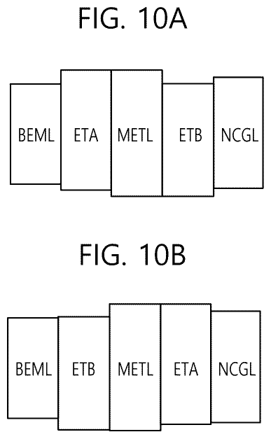

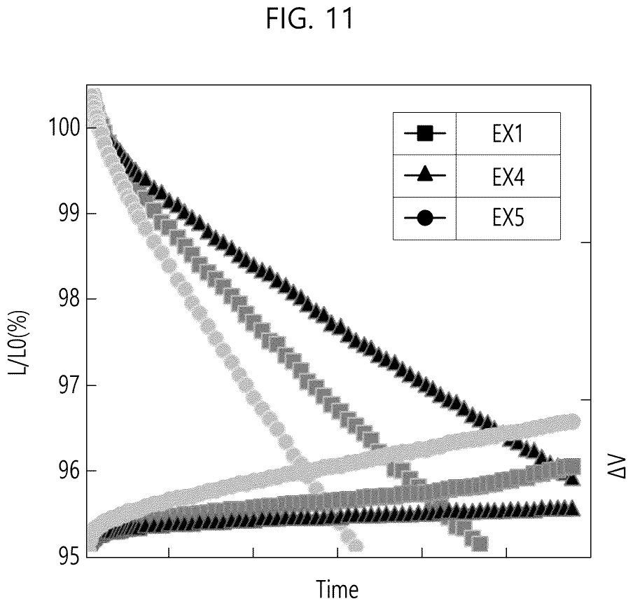

FIGS. 10A and 10B are energy band diagrams of light emitting devices according to Experimental Examples 4 and 5. FIG. 11 is a graph showing changes in lifespan and driving voltage of light emitting devices of Experimental Examples 1, 4, and 5.

In the light emitting device according to Experimental Example 4 EX4 of FIG. 10A, the electron transport stack includes, as shown in FIG. 2, a first material layer ETL1, which is formed of only a first material ETA having a LUMO energy level higher than a LUMO energy level of a host of the light emitting layer, and is disposed in contact with the light emitting layer, a second material layer ETL2, which is formed of only a second material ETB having a LUMO energy level lower than a LUMO energy level of an n-type charge generation layer and is disposed in contact with the n-type charge generation layer, and a combination layer METL in which the first and second materials are mixed in a content ratio of 1:1 between the first and second material layers.

In the light emitting device according to Experimental Example 5 EX5 of FIG. 10B, the electron transport stack includes a second material layer, which is formed of only a second material ETB having a LUMO energy level lower than a LUMO energy level of an n-type charge generation layer, and is disposed in contact with the light emitting layer, a first material layer, which is formed of only a first material ETA having a LUMO energy level higher than a LUMO energy level of a light emitting layer and is disposed in contact with the n-type charge generation layer, and a combination layer METL in which the first and second materials are mixed in a content ratio of 1:1 between the first and second material layers.

In Experimental Examples 4 and 5 EX4 and EX5, the thickness of the combination layer was commonly set to 30% of the total thickness of the electron transport stack.

TABLE 4

| | IVL (10 mA/cm²) | | | 100 mA/cm² | Lifespan |
|---|---|---|---|---|---|
| | Voltage | Luminance | QE | Voltage | (T95 |
| | [V] | [%] | [%] | [V] | [%]) |
| EX4 | Vr1 + 0.03 | 100.0 | 100.1 | Vr2 − 0.01 | 146.5 |
| EX5 | Vr1 − 0.06 | 98.5 | 98.5 | Vr2 − 0.01 | 67.5 |

As shown in Table 4 and FIG. 11, when comparing the characteristics of Experimental Example 4 EX4 and Experimental Example 5 EX5 with the results of Experimental Example 1 EX1, it can be seen that Experimental Example 4 EX4 has a significantly improved lifespan because it does not have an energy barrier at both interfaces with the electron transport stack. In addition, as can be seen from FIG. 11, in the light emitting devices of Experimental Example 1 EX1, Experimental Example 4 EX4, and Experimental Example 5 EX5, the driving voltage change (ΔV) over time is significantly reduced in Experimental Example 4 EX4.

Experimental Example 5 EX5 has a short lifespan and a large driving voltage change (ΔV) over time compared to Experimental Example 1 EX1, which means that the energy barrier in the electron transport flow at the interface of the electron transport stack acts as a stress during driving, which reduces the electron injection efficiency into the light emitting layer and reduces the lifespan.

Hereinafter, the driving voltage and luminance of other experimental examples were compared with Experimental Example 1 EX1 described above depending on the thickness ratio of the combination layer within the electron transport stack through the experiments in Table 5.

Experimental Example 6 EX6 provides an electron transport stack that includes a first material layer ETL1 of a single first material ETA and a second material layer ETL2 of a single second material ETB, while excluding a combination layer.

Experimental Example 7 EX7 provides an electron transport stack that includes a first material layer ETL1 of a single first material ETA, a second material layer ETL2 of a single second material ETB, and a combination layer METL in which the first and second materials are mixed in a content ratio of 1:1 between the first and second material layers, but the thickness of the combination layer METL is 15% of the total thickness of the electron transport stack.

Experimental Example 8 EX8 provides an electron transport stack that includes a first material layer ETL1 of a single first material ETA, a second material layer ETL2 of a single second material ETB, and a combination layer METL in which the first and second materials are mixed in a content ratio of 1:1 between the first and second material layers, but the thickness of the combination layer METL is 30% of the total thickness of the electron transport stack.

TABLE 5

| | IVL (10 mA/cm²) | | | 100 mA/cm² | Lifespan |
|---|---|---|---|---|---|
| | Voltage | Luminance | QE | Voltage | (T95 |
| | [V] | [%] | [%] | [V] | [%]) |
| EX1 | Vr1 | 100.0 | 100 | Vr2 | 100 |
| EX6 | Vr1 + 0.04 | 100 | 100 | Vr2 + 0.01 | 145 |
| EX7 | Vr1 + 0.04 | 99 | 99 | Vr2 + 0.01 | 144 |
| EX8 | Vr1 + 0.03 | 101 | 101 | Vr2 − 0.01 | 146 |

As can be seen from Table 5, the electron transport stack ETLS is effective in the lifespan even when it has a double-layer configuration where different materials are in contact, such as the light emitting device of Experimental Example 6 EX6.

In addition, as can be seen from Table 5, the luminance, quantum efficiency, driving voltage at high current density, and lifespan are most effective when the thickness of the combination layer is 30% of the electron transport stack ETLS.

Meanwhile, the results of Table 5 show the significance of the electron transport stack ETLS in which the first material layer ETL1 formed of only the first material ETA and the second material layer ETL2 formed of only the second material ETB is essentially provided.

The combination layer METL can be a component that is necessarily generated in the process of forming the electron transport stack ETLS including the first and second materials ETA and ETB. Meanwhile, the results in Table 5 show that the thickness of the combination layer METL is set to be not less than 15% and less than 50% of the thickness of the entire electron transport stack ETLS, thereby sufficiently securing the arrangement of the first material layer ETL1 and the second material layer ETL2 within the electron transport stack ETLS.

Hereinafter, the characteristics of the light emitting device will be described when the mixing ratio of the first and second materials ETA and ETB contained in the combination layer METL is changed while the combination layer METL is maintained at 30% of the entire thickness of the electron transport stack ETLS.

Experimental Example 1 EX1 has a configuration in which the first material ETA and the second material ETB are co-deposited in a content ratio of 1:1 (=5:5).

Compared to Experimental Example 1 EX1, Experimental Example 8 EX8, Experimental Example 9 EX9, and Experimental Example 10 EX10 each have a first material layer ETL1 of a single first material ETA, a second material layer ETL2 of a single second material ETB, and a combination layer METL with a thickness of 30% of the total thickness of the electron transport stack ETLS between the first and second material layers ETL1 and ETL2.

Experimental Example 8 EX8 has a configuration in which the first material ETA and the second material ETB in the combination layer METL are present in a ratio of 5:5.

Experimental Example 9 EX9 has a configuration in which the content ratio of the first material ETA and the second material ETB in the combination layer METL is 6:4, and the content of the first material ETA is higher than that of the second material ETB.

Experimental Example 10 EX10 has a configuration in which the content ratio of the first material ETA and the second material ETB in the combination layer METL is 4:6 and the content of the second material ETB is higher than that of the first material ETA.

As can be seen from the results in Table 6 below, when the content of the first material ETA and the second material ETB in the combination layer METL is the same or the content of the second material EB is higher, the driving voltage is reduced, and the luminance and quantum efficiency are improved. However, even when the content of the first material ETA in the combination layer METL is greater than that of the second material ETB, the driving voltage or luminance change is almost the same level as in Experimental Example 1 EX1.

TABLE 6

| | Content | IVL (10 mA/cm²) | | | 100 mA/cm² |
|---|---|---|---|---|---|
| | ratio | Voltage | Luminance | QE | Voltage |
| Item | ETA:ETB | [V] | (Cd/A)(%) | (%) | [V] |
| EX1 | ETA/ETB | Vr1 | 100.0 | 100 | Vr2 |
| | (1:1) | | | | |
| EX9 | 6:4 | Vr1 + 0.06 | 99 | 99 | Vr2 + 0.03 |
| EX8 | 5:5 | Vr1 + 0.03 | 101 | 101 | Vr2 − 0.01 |
| EX10 | 4:6 | Vr + 0.02 | 101 | 101 | Vr2 − 0.01 |

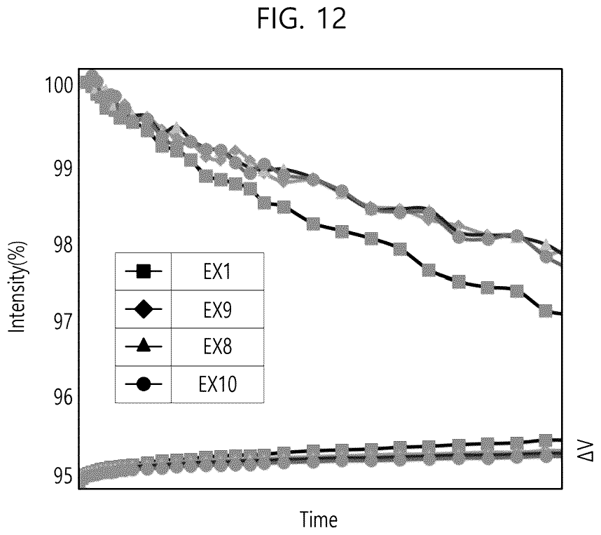

FIG. 12 is a graph showing the lifespan and driving voltage change of the light emitting devices of Experimental Example 1 and Experimental Examples 8 to 10.

As can be seen from FIG. 12, regarding the lifespan depending on mixing ratio in the combination layer within the electron transport stack ETLS, the lifespan is commonly improved in Experimental Examples 8 to 10 EX8, EX9, and EX10, compared to Experimental Example 1 EX1.

In addition, regarding the driving voltage change depending on the mixing ratio in the combination layer within the electron transport stack ETLS, as can be seen from FIG. 12, the driving voltage change is commonly reduced in Experimental Examples 8 to 10 EX8, EX9, and EX10, compared to Experimental Example 1 EX1.

For example, it can be seen from the results of experiments that, when the electron transport stack has a combination layer METL between the first and second material layers, and the contents of the first material ETA and the second material ETB in the combination layer METL are equal or similar, the efficiency and luminance are at equal levels, the lifespan is improved, and the stability of the driving voltage change is secured.

Hereinafter, other embodiments of the present disclosure will be described.

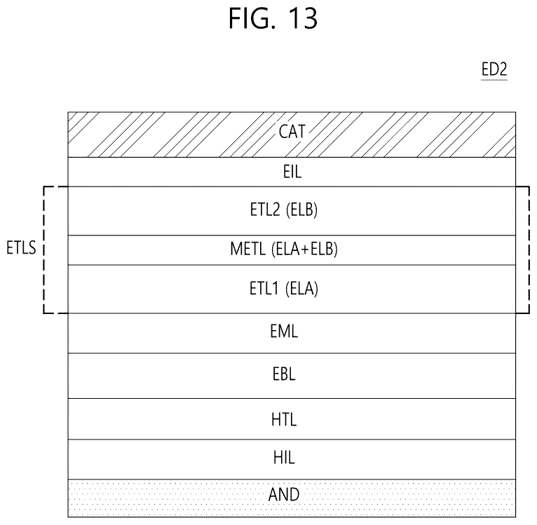

FIG. 13 is a cross-sectional view illustrating a light emitting device according to a second embodiment of the present disclosure.

As shown in FIG. 13, the light emitting device ED2 according to the second embodiment of the present disclosure includes a hole injection layer HIL, a hole transport layer HTL, an electron blocking layer EBL, a light emitting layer EML, an electron transport stack ETLS, and an electron injection layer EIL sequentially between the first electrode AND and the second electrode CAT.

The electron transport stack ETLS is disposed between the light emitting layer EML and the electron injection layer EIL.

The electron injection layer EIL has a higher LUMO energy level than the second material layer ETL2 formed of a single second material ETB, like the n-type charge generation layer of FIG. 2, so that electrons are sequentially injected from the electron injection layer EIL to the second material layer ETL2 without an energy barrier. In addition, in the combination layer METL of the first and second materials ETA and ETB, electrons can be transported in a configuration having continuity of materials, and electrons can be transferred to the light emitting layer EML without an energy barrier based on the LUMO energy level relationship that gradually decreases from the first material layer ETL1 of the single configuration of the first material ETA to the light emitting layer EML.

Here, the electron injection layer EIL can include the material of the n-type charge generation layer described above.

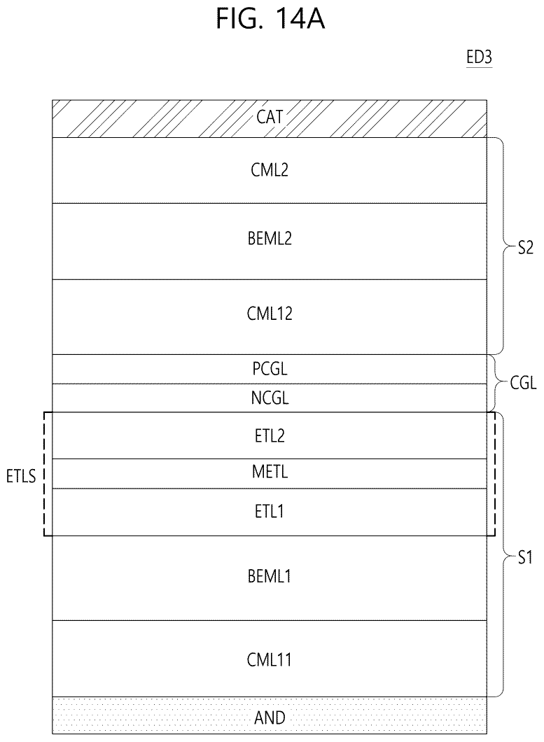

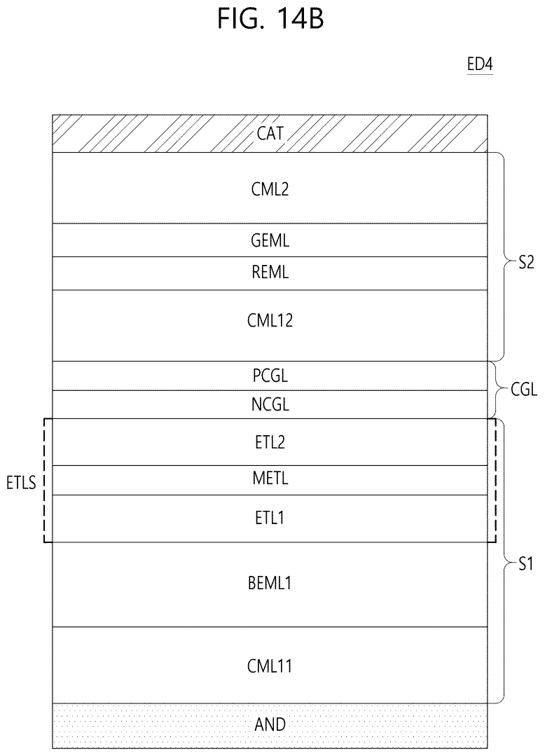

FIGS. 14A and 14B are cross-sectional views illustrating modifications of the first embodiment of the present disclosure.

The light emitting device ED3 according to the embodiment according to FIG. 14A has a configuration in which the first light emitting stack S1 and the second light emitting stack S2 are provided with the same blue light emitting layer BEML1, BEML2. The first light emitting stack S1 has a first blue light emitting layer BEML1 and the second light emitting stack S2 has a second blue light emitting layer BEML2.

The first light emitting stack S1 has a first hole-transporting common layer CML11 between the first electrode AND and the first blue light emitting layer BEML1, and the second light emitting stack S2 has a first hole-transporting common layer CML12 between the charge generation layer CGL and the second blue light emitting layer BEML2. The first hole-transporting common layers CML11 and CML12 can include a hole injection layer HIL, a hole transport layer HTL, an electron blocking layer EBL, and the like.

The charge generation layer CGL includes an n-type charge generation layer NCGL and a p-type charge generation layer PCGL.

The light emitting device ED3 according to the embodiment of FIG. 14A has a configuration of an n-type charge generation layer NCGL among the charge generation layers CGL between the first light emitting stack S1 and the second light emitting stack S2, and an electron transport stack ETLS between the first blue light emitting layer BEML1 in the first light emitting stack S1. The electron transport stack ETLS includes a first material layer ETL1 including only a first material ETA adjacent to the first blue light emitting layer BEML1, a second material layer ETL2 including only a single second material ETB different from the first material ETA adjacent to the n-type charge generation layer NCGL, and a combination layer METL of the first material ETA and the second material ETB between the first material layer ETL1 and the second material layer ETL2. The first material ETA has a higher LUMO energy level than the LUMO energy level of the host of the first blue light emitting layer BEML1, and the second material ETB has a lower LUMO energy level than the LUMO energy level of the n-type charge generation layer NCGL, and has effects of increasing the lifespan and efficiency of the electron transport stack described above.

In some cases, the electron transport common layer CML2 of the second emitting stack S2 of the light emitting device ED3 can also include the structure of the electron transport stack described above. In this case, an electron injection layer can be further provided between the electron transport stack and the second electrode CAT.

The light emitting device ED4 according to the embodiment according to FIG. 14B shows a configuration in which different emitting layers are provided in the first emitting stack S1 and the second emitting stack S2. The first light emitting stack S1 can include a blue light emitting layer BEML1, and the second light emitting stack S2 can include a configuration of a phosphorescent light emitting layer including at least a red light emitting layer REML and a green light emitting layer GEML.

The light emitting device ED4 according to the embodiment of FIG. 14B also has a configuration of an electron transport stack ETLS between an n-type charge generation layer NCGL among charge generation layers CGL between the first light emitting stack S1 and the second light emitting stack S2, and a blue light emitting layer BEML in the first light emitting stack S1. An electron transport stack ETLS includes a first material layer ETL1 including only a first material ETA adjacent to a blue light emitting layer BEML, a second material layer ETL2 including only a second material ETB different from the first material ETA adjacent to an n-type charge generation layer NCGL, and a combination layer METL of the first material ETA and the second material ETB between the first material layer ETL1 and the second material layer ETL2. The first material ETA has a LUMO energy level higher than a LUMO energy level of a host of the blue light emitting layer BEML, and the second material ETB has a LUMO energy level lower than a LUMO energy level of the n-type charge generation layer NCGL, and has the effects of increasing the lifespan and enhancing the efficiency of the electron transport stack as described above.

In some cases, the electron transport common layer CML2 of the second light emitting stack S2 of the light emitting device ED can also include the structure of the electron transport stack described above. In this case, an electron injection layer can be further provided between the electron transport stack and the second electrode CAT.

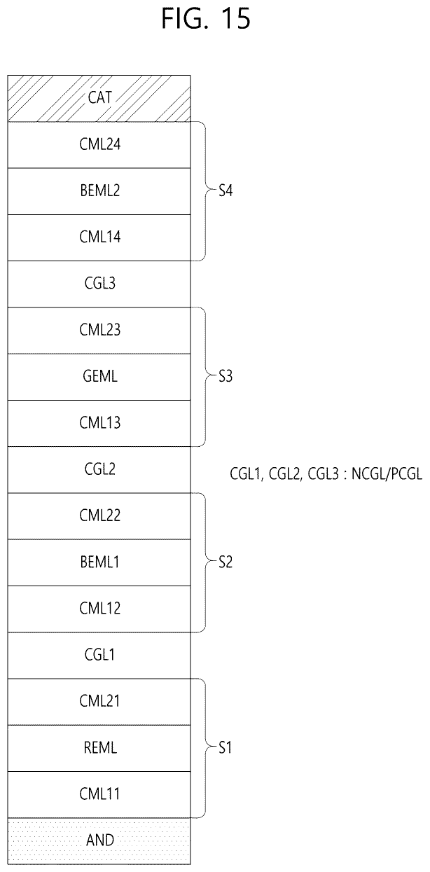

FIG. 15 is a cross-sectional view illustrating a light emitting device according to a third embodiment of the present disclosure.

As shown in FIG. 15, the light emitting device according to the third embodiment of the present disclosure is provided as an example having a 4-stack (i.e., light emitting stacks S1, S2, S3, S4) tandem structure.

For example, the light emitting device of FIG. 15 includes a red light emitting layer REML, a first blue light emitting layer BEML1, a green light emitting layer GEML, and a second blue light emitting layer BEML2 with charge generation layers CGL1, CGL2, CGL3 interposed therebetween from the first electrode AND to the second electrode CAT, and a hole-transporting common layer CML11, CML12, CML13, CML14 under the light emitting layers of each light emitting stack, and electron-transporting common layers CML21, CML22, CML23, CML24 on the light emitting layers of each light emitting stack. In this case, at least one of the electron-transporting common layers CML21, CML22, CML23, and CML24 is replaced with the electron-transporting stack described above, to improve the electron-transporting efficiency and the lifespan of the light emitting device.

Hereinafter, an example in which a light emitting device described above is applied to a light emitting display device will be described.

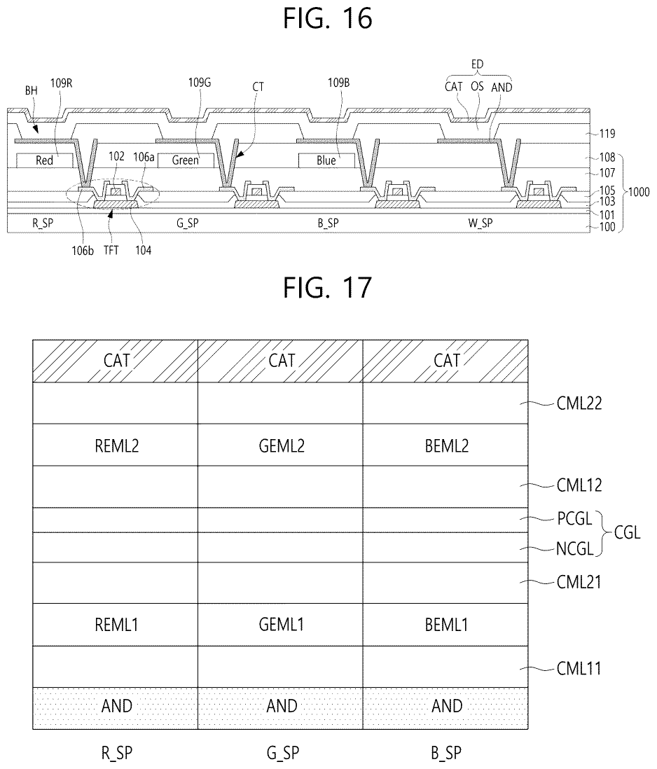

As shown in FIG. 16, a light emitting display device according to an embodiment of the present disclosure can emit light through a first electrode AND on an emission side by applying the light emitting device described above to at least one of a plurality of sub-pixels R_SP, G_SP, B_SP, and W_SP.

The light emitting device ED of each sub-pixel can include a first electrode AND, a second electrode CAT, and an intermediate layer OS. The intermediate layer OS can include a plurality of light emitting stacks and have the same configuration in the plurality of sub-pixels R_SP, G_SP, B_SP, W_SP. In addition, the intermediate layer OS can include the electron transport stack between the plurality of light emitting stacks and the charge generation layer.

As shown in FIG. 16, the light emitting display device according to an embodiment of the present disclosure can include a substrate 100 on which a plurality of sub-pixels R_SP, G_SP, B_SP, W_SP are disposed, a light emitting device ED commonly provided on the substrate 100, a thin film transistor TFT provided in each of the sub-pixels R_SP, G_SP, B_SP, W_SP and connected to the first electrode AND of the light emitting device ED, and a color filter layer 109R, 109G, 109B provided under the first electrode AND of at least one of the sub-pixels.

The example in FIG. 16 shows a case in which a white sub-pixel W_SP is included in the light emitting display device, but the present disclosure is not limited thereto, and a structure in which the white sub-pixel W_SP is omitted and only red, green, and blue sub-pixels R_SP, G_SP, B_SP are provided can also be possible. In some cases, a combination of cyan sub-pixels, magenta sub-pixels, and yellow sub-pixels that can express white by replacing red, green, and blue sub-pixels is also possible.

The thin film transistor TFT includes, for example, a gate electrode 102, a semiconductor layer 104, and a source electrode 106a and a drain electrode 106b connected to both sides of the semiconductor layer 104. In addition, a channel protection layer can be further provided on an upper portion of a portion where a channel of the semiconductor layer 104 is located to prevent direct connection between the source/drain electrodes 106a, 106b and the semiconductor layer 104. A buffer layer 101 can be disposed on a substrate 100 and the thin film transistor TFT can be located on the buffer layer 101.

A gate insulating film 103 is provided between the gate electrode 102 and the semiconductor layer 104.

The semiconductor layer 104 can be formed of, for example, an oxide semiconductor, amorphous silicon, polycrystalline silicon, or a combination of two or more thereof. For example, when the semiconductor layer 104 is an oxide semiconductor, the heating temperature required to form a thin film transistor can be lowered, so that the substrate 100 can be used with a high degree of freedom, which makes it advantageous for application to a flexible display device.

A gate electrode 102 can be provided on the gate insulating film 103 and an interlayer insulating film 105 can be further provided between the gate electrode 102 and the source electrode 106a/drain electrode 106b.

In addition, the drain electrode 106b of the thin film transistor TFT can be connected to the first electrode AND through the contact hole CT provided in the first and second protective films 107 and 108.

The first protective film 107 is provided primarily to protect the thin film transistor TFT, and a color filter 109R, 109G, 109B can be provided on the first protective film 107.

A second protective film 108 is provided on the first protective film 107 including the color filter 109R, 109G, 109B.

When a plurality of sub-pixels includes a red sub-pixel R_SP, a green sub-pixel G_SP, a blue sub-pixel B_SP, and a white sub-pixel W_SP, as shown in FIG. 16, the color filters are provided as first to third color filters 109R, 109G, 109B for the remaining sub-pixels R_SP, G_SP, B_SP except for the white sub-pixel W_SP, so as to allow white light emitted through the first electrode AND to pass according to each wavelength. In addition, a second protective film 108 is formed under the first electrode AND to cover the first to third color filters 109R, 109G, 109B. The first electrode AND is formed on the surface of the second protective film 108 excluding the contact hole CT and is connected to one of the drain electrode 106b and the source electrode 106a of the thin film transistor TFT to receive an electrical signal from the thin film transistor TFT.

Here, the thin film transistor array substrate 1000 can include the substrate 100, the thin film transistor TFT, the color filter 109R, 109G, 109B, and the first and second protective films 107 and 108.

The light emitting device ED is provided on a thin film transistor array substrate 1000 including a bank 119 defining a light emitting portion BH. For example, the light emitting device ED can include a plurality of light emitting stacks S1 and S2, and a charge generation layer CGL between adjacent light emitting stacks S1 and S2 as the light emitting devices ED1, ED3 and ED4 a LUMO energy level of an n-type charge generation layer shown in FIGS. 1, 14A and 14B or the light emitting device having the plurality of light emitting stacks S1, S2, S3 and S4 and charge generation layers CGL1, CGL2, and CGL3 between the transparent first electrode AND and the second electrode CAT shown in FIG. 15. The light emitting device ED can include the electron transport stack ETLS as described above. For example, the light emitting device ED comprises the light emitting device as shown in FIG. 15, the electron-transporting common layers CML21, CML22, CML23, and CML24 is replaced with the electron-transporting stack ETLS described above.

The first electrode AND is divided into each sub-pixel, and the remaining layers excluding the first electrode AND of the light emitting device ED can be provided as an integral part in the entire display area without distinction by sub-pixel.

Either the first electrode AND or the second electrode CAT can be connected to a thin film transistor TFT.

When an electron transport stack structure is applied between at least one light emitting stack and a charge generation layer in the light emitting display device of the present disclosure described above, the effects of improving efficiency and lifespan can be obtained.

Meanwhile, the light emitting display device of FIG. 16 described above is illustrated as a structure in which light is emitted downward, but the present disclosure is not limited thereto. For example, the first electrode AND includes a reflective electrode, the second electrode CAT is a transparent electrode or a reflective-transparent electrode, and the color filter is disposed above the second electrode CAT so that the light emitting display device can be applied in a top-emission manner.

In the structure described above, the intermediate layer OS of the light emitting device ED is common to each sub-pixel, but the light emitting display device of the embodiment of the present disclosure is not limited thereto.

FIG. 17 is a cross-sectional view illustrating a light emitting display device according to the second embodiment of the present disclosure.

As shown in FIG. 17, in addition, the light emitting display device according to one embodiment of the present disclosure can include a first electrode AND and a second electrode CAT facing each other in each of a red sub-pixel R_SP, a green sub-pixel G_SP, and a blue sub-pixel B_SP, and a plurality of light emitting stacks between the first electrode AND and the second electrode CAT, wherein the plurality of light emitting stacks has overlapping light emitting layers that emit light of the same color. For example, the red sub-pixel R_SP can have red light emitting layers REML1 and REML2 in separate light emitting stacks with a charge generation layer CGL disposed therebetween, the green sub-pixel G_SP can have green light emitting layers GEML1 and GEML2 in separate light emitting stacks with a charge generation layer CGL disposed therebetween, and the blue sub-pixel B_SP can have blue light emitting layers BEML1 and BEML2 in separate light emitting stacks with a charge generation layer CGL disposed therebetween.

Here, a hole-transporting common layer CML11 related to hole injection and hole transport is provided between the first electrode AND and the first red light emitting layer REML1, the first green light emitting layer GEML1, and the first blue light emitting layer BEML1, and an electron-transporting common layer CML21 related to electron transport is provided between the first red light emitting layer REML1, the first green light emitting layer GEML1, and the first blue light emitting layer BEML1 and the charge generation layer CGL.

The charge generation layer CGL can be provided by laminating an n-type charge generation layer nCGL and a p-type charge generation layer pCGL. In addition, a hole-transporting common layer CML12 related to hole injection and hole transport can be provided between the charge generation layer CGL and the second red light emitting layer REML2, the second green light emitting layer GEML2, and the second blue light emitting layer BEML2, and an electron-transporting common layer CML22 including an electron transport layer and an electron injection layer can be provided between the second red light emitting layer REML2, the second green light emitting layer GEML2, and the second blue light emitting layer BEML2 and the second electrode CAT.

The hole-transporting common layers CML11 and CML12 related to hole injection and transport can include at least one of a hole injection layer, a hole transport layer, and an electron blocking layer, and the electron-transporting common layers CML21 and CML22 related to electron transport and injection can include at least one of a hole blocking layer, an electron transport layer, and an electron injection layer.

Here, at least one of the electron-transporting common layers CML21 and CML22 related to electron transport and injection can obtain the effects of improving electron transport efficiency and lifespan by including the configuration of the electron transport stack ETLS described in FIGS. 1 to 6.

The light emitting display device according to one embodiment of the present disclosure can include a substrate on which a plurality of sub-pixels is disposed, a pixel circuit provided in each of the plurality of sub-pixels, and the light emitting device described above connected to a thin film transistor of the pixel circuit.

The light emitting display device according to one embodiment of the present disclosure can include a substrate on which a plurality of sub-pixels is disposed, a pixel circuit provided in each of the plurality of sub-pixels, a first electrode connected to a thin film transistor of the pixel circuit in each of the plurality of sub-pixels, a second electrode facing the first electrode, and a first light emitting stack, a charge generation layer including an n-type charge generation layer and a p-type charge generation layer, and a second light emitting stack provided between the first electrode and the second electrode, wherein the first light emitting stack includes a light emitting layer and an electron transport stack, the light emitting layer includes first to third color light emitting layers emitting light of different colors, and the electron transport stack can include a first material layer including only a first electron transport material adjacent to the first to third color light emitting layers, a second material layer including only a second electron transport material different from the first electron transport material adjacent to the n-type charge generation layer, and a combination layer of the first electron transport material and the second electron transport material between the first material layer and the second material layer.

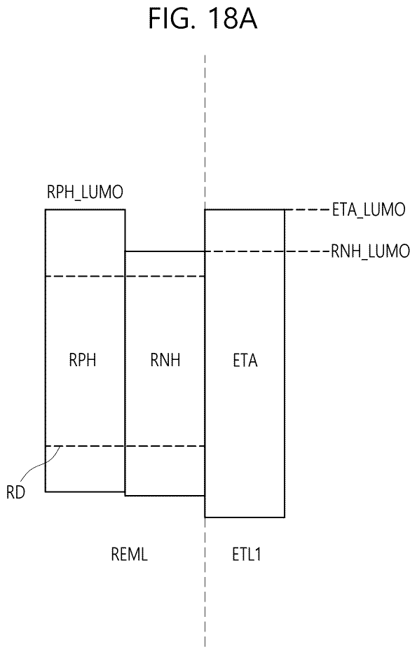

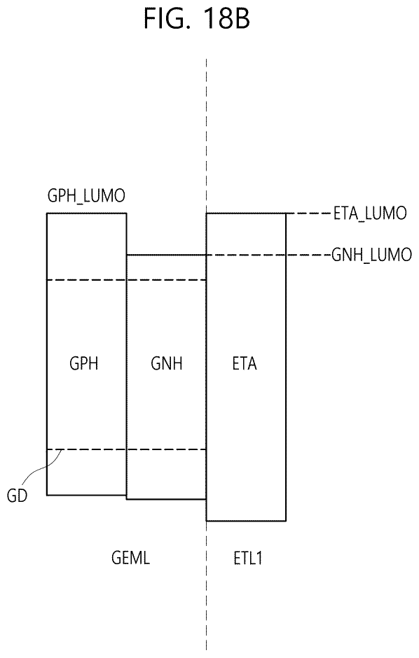

FIG. 18A is an energy band diagram of a first material layer of an electron transport stack adjacent to a red light emitting layer. FIG. 18B is an energy band diagram of a first material layer of an electron transport stack adjacent to a green light emitting layer.

As shown in FIG. 17, adjacent red sub-pixels R_SP, green sub-pixels G_SP, and blue sub-pixels B_SP share common layers CML11, CML21, CML12, CML22. When the electron transport common layers CML21 and CML22 in contact with the blue light emitting layers BEML1, BEML2 have a configuration of the electron transport stack ETL2 of FIGS. 1 and 2, these common layers CML21 and CML22 are also in contact with the red light emitting layers REML1, REML2, and the green light emitting layers GEML1, GMLE2. Therefore, as shown in FIG. 18A, the red light emitting layer REML is in contact with the first material layer ETL1 of the first material ETA, and as shown in FIG. 18B, the green light emitting layer GEML is in contact with the first material layer ETL1 of the first material ETA.

In this case, the red light emitting layer REML includes a p-type host RPH and an n-type host RNH. The p-type host RPH is a hole-transporting host and the n-type host RNH is an electron-transporting host. When the n-type host RNH has a lower LUMO energy level than the p-type host RPH, and the first material layer ETL1 and the red light emitting layer REML in the electron-transporting stack are in contact, the n-type host RNH having a lower LUMO energy level can act at the interface therebetween. Therefore, in the red sub-pixel R_SP, the LUMO energy level from the first material layer ETL1 to the red light emitting layer REML is changed from a high state to a low state, so that there is no energy barrier in the flow of electrons, there is no increase in the driving voltage, the injection of electrons into the red light emitting layer can be facilitated and the lifespan can be increased.

In addition, as shown in FIG. 18B, the green light emitting layer GEML includes a p-type host GPH and an n-type host GNH. The p-type host GPH is a hole-transporting host and the n-type host GNH is an electron-transporting host. When the n-type host GNH has a lower LUMO energy level than the p-type host GPH, and the first material layer ETL1 and the green light emitting layer GEML in the electron transport stack come into contact, the n-type host GNH having a lower LUMO energy level can act at the interface therebetween. Therefore, in the green sub-pixel G_SP, the LUMO energy level from the first material layer ETL1 to the green light emitting layer GEML is changed from a high state to a low state, so that there is no energy barrier in the flow of electrons, there is no increase in the driving voltage, the injection of electrons into the green light emitting layer is facilitated, and the lifespan is increased.

The blue sub-pixel is as described in FIGS. 1 to 6.

The light emitting device according to one or more embodiments of the present disclosure includes a first electron-transporting single layer having a single first electron-transporting material, a second electron-transporting single layer having a single second electron-transporting material, and a combination region between the first and second electron-transporting single layers.

A plurality of electron-transporting layer stacks is provided, and the difference in LUMO energy level between the first electron-transporting single layer and the second electron-transporting single layer, which are adjacent components between the light emitting layer and the charge generation layer improves the lifespan without an energy barrier on the electron-transporting flow. In a multilayer electron transport layer structure, the lifespan of blue light can be improved by reducing the barrier between the electron transport layer and the light emitting layer, between the electron transport layer and the charge generation layer, or between the electron transport layer and the electron injection layer.

A light emitting device according to one embodiment of the present disclosure can comprise a first electrode and a second electrode facing each other and a first light emitting layer, an electron transport stack, and a charge generation layer provided between the first electrode and the second electrode. The electron transport stack can comprise a first material layer adjacent to the first light emitting layer and including a single first material, a second material layer adjacent to the charge generation layer and including a single second material different from the first material and a combination layer of the first material and the second material between the first material layer and the second material layer.

In a light emitting device according to one embodiment of the present disclosure, the first material can be an electron transport material having a first LUMO energy level higher than a LUMO energy level of a host of the first light emitting layer. The second material can be an electron transport material having a second LUMO energy level lower than a LUMO energy level of the charge generation layer.

In a light emitting device according to one embodiment of the present disclosure, an absolute value of the first LUMO energy level can be smaller than an absolute value of the second LUMO energy level.

In a light emitting device according to one embodiment of the present disclosure, the first material can have a triplet energy level of 2.5 eV or more, and has a larger energy band gap than each of the host of the first light emitting layer, the second material, and the charge generation layer adjacent to the second material layer.

In a light emitting device according to one embodiment of the present disclosure, the first material can have an energy band gap of 3.5 eV or more and is bipolar.

In a light emitting device according to one embodiment of the present disclosure, the charge generation layer can comprise an n-type charge generation layer and a p-type charge generation layer. The light emitting layer can be in contact with the first material layer of the electron transport stack. The n-type charge generation layer can be in contact with the second material layer of the electron transport stack.

In a light emitting device according to one embodiment of the present disclosure, the charge generation layer can comprise an n-type charge generation layer and a p-type charge generation layer. A LUMO energy level of the n-type charge generation layer can be higher than a LUMO energy level of the light emitting layer.

In a light emitting device according to one embodiment of the present disclosure, the n-type charge generation layer comprises a third material doped with an alkali metal. The third material can have a larger energy band gap and a higher LUMO energy level than the second material.

In a light emitting device according to one embodiment of the present disclosure, the combination layer can have a thickness smaller than or equal to a total thickness of the first material layer and the second material layer.

In a light emitting device according to one embodiment of the present disclosure, the light emitting device can further comprise a first common layer between the first electrode and the first light emitting layer, and at least one light emitting stack, each light emitting stack comprising a second common layer, a second light emitting layer, and a third common layer between the charge generation layer and the second electrode.

In a light emitting device according to one embodiment of the present disclosure, the second light emitting layer can emit light of color different from the first light emitting layer.

In a light emitting device according to one embodiment of the present disclosure, the first light emitting layer and the second light emitting layer can emit blue light.

In a light emitting device according to one embodiment of the present disclosure, the second light emitting layer can include a plurality of light emitting layers, each of which emits a light of a longer wavelength than the first light emitting layer.

In a light emitting device according to one embodiment of the present disclosure, the first light emitting layer can be a blue light emitting layer, and the second light emitting layer can comprise at least a red light emitting layer and a green light emitting layer.

In a light emitting device according to one embodiment of the present disclosure, the third common layer can comprise a third material layer adjacent to the second light emitting layer and including a single third material, a fourth material layer adjacent to the second electrode and including a single fourth material different from the third material and a combination layer of the third material and the fourth material between the third material layer and the fourth material layer. The third material can be an electron transport material having a third LUMO energy level higher than the LUMO energy level of the host of the second light emitting layer. The fourth material can be an electron transport material having a fourth LUMO energy level lower than the LUMO energy level of an organic material layer in contact with the fourth material layer.

In a light emitting device according to one embodiment of the present disclosure, the organic material layer can be an electron injection layer.

In a light emitting device according to one embodiment of the present disclosure, the organic material layer can be an n-type charge generation layer.

In a light emitting device according to one embodiment of the present disclosure, electrons can be sequentially transferred in the direction in which electrons are transported from the charge generation layer to the first light emitting layer at both interfaces of the electron transport stack.

In a light emitting device according to one embodiment of the present disclosure, the first and second material layers each can have a thickness of 25 Å or more.

In a light emitting device according to one embodiment of the present disclosure, a total thickness of the electron transport stack can be set to be higher than 70 Å and not higher than 350 Å.

In a light emitting device according to one embodiment of the present disclosure, a thickness of the combination layer can be set to be not less than 15% and less than 50% of a thickness of the entire electron transport stack.

In a light emitting device according to one embodiment of the present disclosure, the contents of the first material and the second material in the combination layer can be equal or similar.

In a light emitting device according to one embodiment of the present disclosure, the second material can have unipolarity.

A light emitting device according to one embodiment of the present disclosure can comprise a substrate on which a plurality of sub-pixels is disposed, a pixel circuit disposed in each of the plurality of sub-pixels and the light emitting device described above, the light emitting device connected to a thin film transistor of the pixel circuit.

A light emitting display device according to one embodiment of the present disclosure can comprise a substrate on which a plurality of sub-pixels, a pixel circuit disposed in each of the plurality of sub-pixels, a first electrode connected to a thin film transistor of the pixel circuit in each of the plurality of sub-pixels, a second electrode facing the first electrode and a first light emitting stack, a charge generation layer comprising an n-type charge generation layer and a p-type charge generation layer, and a second light emitting stack, provided between the first electrode and the second electrode. The first light emitting stack can comprise a light emitting layer and an electron transport stack. The light emitting layer can comprise first, second and third color light emitting layers emitting light of different colors.

The electron transport stack can comprise a first material layer adjacent to the first to third color light emitting layers and including a single first electron transport material, a second material layer adjacent to the n-type charge generation layer and including a single second electron transport material different from the first electron transport material and a combination layer of the first electron transport material and the second electron transport material between the first material layer and the second material layer.

In a light emitting display device according to one embodiment of the present disclosure, the first color light emitting layer can comprise a first host and a blue dopant. The second color light emitting layer can comprise a second host and a green dopant. The third color light emitting layer can comprise a third host and a red dopant.

In a light emitting display device according to one embodiment of the present disclosure, the first electron transport material can have a first LUMO energy level higher than each of the LUMO energy levels of the first to third hosts. The second electron transport material can have a second LUMO energy level lower than a LUMO energy level of the n-type charge generation layer.

In a light emitting display device according to one embodiment of the present disclosure, the first to third hosts can be electron transport hosts. At least one of the first to third color light emitting layers can further comprise a hole transport host having a LUMO energy level higher than a LUMO energy level of the first material layer.

The light emitting device of the present disclosure and the light emitting display device including the same have the following effects.

The light emitting device according to the embodiments of the present disclosure has an electron transport stack in which different materials are disposed for each adjacent functional layer between the light emitting layer and the charge generation layer in the light emitting device including a plurality of light emitting stacks, and is capable of improving the lifespan characteristics because there is no energy barrier when electrons are transferred to the light emitting layer.

The light emitting device and the light emitting display device according to the embodiments of the present disclosure are capable of improving the efficiency of the light emitting layer, thereby reducing driving voltage and improving lifespan. Therefore, the light emitting device and the light emitting display device are continuously applicable, thus achieving ESG (environmental/social/governance) goals.

It will be apparent to those skilled in the art that various modifications and variations can be made in the present disclosure without departing from the spirit or scope of the disclosure. Thus, it is intended that the present disclosure covers the modifications and variations of this disclosure provided they come within the scope of the appended claims and their equivalents.

What is claimed is:

1. A light emitting device comprising:
a first electrode and a second electrode facing each other; and
a first light emitting layer, an electron transport stack, and a charge generation layer provided between the first electrode and the second electrode,
wherein the electron transport stack comprises:
a first material layer adjacent to the first light emitting layer and including a single first material;
a second material layer adjacent to the charge generation layer and including a single second material different from the first material; and
a combination layer of the first material and the second material disposed between the first material layer and the second material layer.

2. The light emitting device according to claim 1, wherein the first material is an electron transport material having a first lowest unoccupied molecular orbital (LUMO) energy level higher than a LUMO energy level of a host of the first light emitting layer, and
the second material is an electron transport material having a second LUMO energy level lower than a LUMO energy level of the charge generation layer.

3. The light emitting device according to claim 2, wherein an absolute value of the first LUMO energy level is smaller than an absolute value of the second LUMO energy level.

4. The light emitting device according to claim 1, wherein the first material has a triplet energy level of 2.5 eV or more, and has a larger energy band gap than each of a host of the first light emitting layer, the second material, and the charge generation layer adjacent to the second material layer.

5. The light emitting device according to claim 1, wherein the first material has an energy band gap of 3.5 eV or more and is bipolar.

6. The light emitting device according to claim 1, wherein the charge generation layer comprises an n-type charge generation layer and a p-type charge generation layer,
the first light emitting layer is in contact with the first material layer of the electron transport stack, and
the n-type charge generation layer is in contact with the second material layer of the electron transport stack.

7. The light emitting device according to claim 1, wherein the charge generation layer comprises an n-type charge generation layer and a p-type charge generation layer, and
a lowest unoccupied molecular orbital (LUMO) energy level of the n-type charge generation layer is higher than a LUMO energy level of the first light emitting layer.

8. The light emitting device according to claim 7, wherein the n-type charge generation layer comprises a third material doped with an alkali metal, and
the third material has a larger energy band gap and a higher LUMO energy level than the second material.

9. The light emitting device according to claim 1, wherein the combination layer has a thickness smaller than or equal to a total thickness of the first material layer and the second material layer.

10. The light emitting device according to claim 1, wherein the light emitting device further comprises:
a first common layer between the first electrode and the first light emitting layer; and
at least one light emitting stack, each light emitting stack comprising a second common layer, a second light emitting layer, and a third common layer between the charge generation layer and the second electrode.

11. The light emitting device according to claim 10, wherein the second light emitting layer is configured to emit light of color different from the first light emitting layer.

12. The light emitting device according to claim 10, wherein the first light emitting layer and the second light emitting layer are configured to emit blue light.

13. The light emitting device according to claim 10, wherein the second light emitting layer includes a plurality of light emitting layers, each of which emits a light of a longer wavelength than the first light emitting layer.

14. The light emitting device according to claim 10, wherein the first light emitting layer is a blue light emitting layer, and
the second light emitting layer comprises at least a red light emitting layer and a green light emitting layer.

15. The light emitting device according to claim 10, wherein the third common layer comprises:
a third material layer adjacent to the second light emitting layer and including a single third material;
a fourth material layer adjacent to the second electrode and including a single fourth material different from the third material; and
a combination layer of the third material and the fourth material disposed between the third material layer and the fourth material layer,
wherein the third material is an electron transport material having a third lowest unoccupied molecular orbital (LUMO) energy level higher than a LUMO energy level of a host of the second light emitting layer, and
the fourth material is an electron transport material having a fourth LUMO energy level lower than a LUMO energy level of an organic material layer in contact with the fourth material layer.

16. The light emitting device according to claim 15, wherein the organic material layer is an electron injection layer.

17. The light emitting device according to claim 15, wherein the organic material layer is an n-type charge generation layer.

18. A light emitting display device comprising:
a substrate including a plurality of sub-pixels;
a pixel circuit at each of the plurality of sub-pixels; and
the light emitting device according to claim 1, the light emitting device connected to a thin film transistor of the pixel circuit.

19. A light emitting display device comprising:
a substrate including a plurality of sub-pixels;
a pixel circuit at each of the plurality of sub-pixels;
a first electrode connected to a thin film transistor of the pixel circuit in each of the plurality of sub-pixels;
a second electrode facing the first electrode; and
a first stack, a charge generation layer comprising an n-type charge generation layer and a p-type charge generation layer, and a second stack, all provided between the first electrode and the second electrode,
wherein the first stack comprises a light emitting layer and an electron transport stack,
the light emitting layer comprises first to third color light emitting layers configured to emit light of different colors to adjacent sub-pixels, and
the electron transport stack comprises:
a first material layer including a single first electron transport material adjacent to the first to third color light emitting layers;
a second material layer adjacent to the n-type charge generation layer, the second material layer including a single second electron transport material different from the first electron transport material; and
a combination layer of the first electron transport material and the second electron transport material disposed between the first material layer and the second material layer.

20. The light emitting display device according to claim 19, wherein the first color light emitting layer comprises a first host and a blue dopant,
the second color light emitting layer comprises a second host and a green dopant, and
the third color light emitting layer comprises a third host and a red dopant.

21. The light emitting display device according to claim 20, wherein the first electron transport material has a first lowest unoccupied molecular orbital (LUMO) energy level higher than each of LUMO energy levels of the first to third hosts, and
the second electron transport material has a second LUMO energy level lower than a LUMO energy level of the n-type charge generation layer.

22. The light emitting display device according to claim 20, wherein the first to third hosts are electron transport hosts, and
at least one of the first to third color light emitting layers further comprises a hole transport host having a lowest unoccupied molecular orbital (LUMO) energy level higher than a LUMO energy level of the first material layer.
